(19) United States
(12) Patent Application Publication
(10) Pub. No.: US 2026/0314193 A1
(43) Pub. Date: Oct. 8, 2026

(54) DISPLAY DEVICE

(71) Applicant: LG Display Co., Ltd., Seoul (KR)

(72) Inventors: Jae Se LEE, Paju-si (KR); Joon Young KWON, Paju-si (KR)

(21) Appl. No.: 19/373,456

(22) Filed: Oct. 29, 2025

(30) Foreign Application Priority Data
Dec. 18, 2024 (KR) 10-2024-0189725

(51) Int. Cl. H10K 59/131; H10K 59/40

(52) U.S. Cl. CPC H10K 59/131; H10K 59/40

(57) ABSTRACT

A display device including: a substrate including a display area and a non-display area; a driving wire extending from the display area to the non-display area; a planarization layer arranged over the driving wire; and a touch wire arranged on the planarization layer. The planarization layer includes a trench extending in the one direction, and the trench does not overlap the touch wire in a plan view.

### CROSS-REFERENCE TO RELATED APPLICATION

Pursuant to 35 U.S.C. § 119(a), this application claims the benefit of an earlier filing date and right of priority to Korean Patent Application No. 10-2024-0189725, filed on Dec. 18, 2024, the disclosure of which is incorporated herein by reference in its entirety.

### TECHNICAL FIELD

The present disclosure generally relates to a display device.

### BACKGROUND

Electroluminescent display devices include inorganic light-emitting display devices and organic light-emitting display devices, differing according to the materials of an emission layer. An active matrix type organic light-emitting display device can include an organic light-emitting diode (hereinafter referred to as “OLED”) which is capable of self-emission of light (e.g., without a separate source of light), and has advantages of fast response speed, high emission efficiency, high luminance, and large viewing angle. The organic light-emitting display device may include pixels, each of which has an OLED formed in it. The organic light-emitting display device has an excellent contrast ratio and color reproducibility as it can express black gray-scales in full black.

Such display device can also include a touch sensor that detects the presence or absence of a user's touch and detects touch coordinates. The touch sensor can detect the presence or absence of the touch and the touch coordinates based on change in the capacitance formed at a plurality of touch electrodes.

### SUMMARY

The display device according to one or more implementations of the present specification may include: a substrate including a display area and a non-display area; a driving wire extending from the display area to the non-display area; a planarization layer arranged on the driving wire; and a touch wire arranged over the planarization layer, wherein the planarization layer includes a trench extending in the one direction, and the trench does not overlap the touch wire in a plan view.

Another implementation of the present disclosure also provides a display device comprising: a substrate including a display area and a non-display area; a driving wire extending from the display area to the non-display area; a planarization layer arranged on the driving wire; and touch wire, the touch wire comprises a first touch wire extending in the display area and a second touch wire extending in the non-display area, the planarization layer includes a trench or an opening, and wherein the trench or the opening does not overlap with the first touch wire in the display area in an up and down direction.

Another implementation of the present disclosure also provides a display device comprising a substrate including a display area and a non-display area; a first wire extending from the display area to the non-display area; a planarization layer disposed on the first wire; and a second wire disposed on the planarization layer, wherein the planarization layer includes a trench, the trench exposing a layer contacting the planarization layer from below the planarization layer, the second wire positioned in the display area is not located directly above the groove.

The display device according to one or more implementations of the present specification can provide various technical benefits. For example, in some scenarios, the display device can help prevent moisture from penetrating into the display area even when the pad part is lifted. Accordingly, the lifespan of the display device may be improved and low-power operation may be enabled.

The effects of the present specification are not limited to the effects mentioned above, and other effects not mentioned will be apparent to one having ordinary skill in the art to which the technical ideas of the present specification belong from the following description.

### BRIEF DESCRIPTION OF THE DRAWINGS

FIG. 1 is a diagram of an example of a display device according to an implementation of the present specification;

FIG. 2 is a circuit diagram of an example of the display device according to an implementation of the present specification;

FIG. 3 is a cross-sectional view of an example of a pixel according to an implementation of the present specification;

FIG. 4 is an enlarged view of an example of a portion of a non-display area according to an implementation of the present specification;

FIG. 5 is a diagram showing an example of an open area of a planarization layer according to an implementation of the present specification;

FIG. 6 is a cross-sectional view taken along the line A-A′ of FIG. 4;

FIG. 7 is a cross-sectional view taken along the line B-B′ of FIG. 4;

FIG. 8 is a cross-sectional view of an example of the display device according to an implementation of the present specification;

FIG. 9 is a diagram showing an example of an opening hole formed in the planarization layer according to an implementation of the present specification;

FIG. 10 is a cross-sectional view taken along the line C-C′ of FIG. 9; and

FIG. 11 is a cross-sectional view of an example of a display device according to another implementation of the present specification.

### DETAILED DESCRIPTION

Implementations of the present disclosure can provide a display device capable of preventing moisture penetration.

In general, a display device can have problems when a pad part separates and lifts in a high temperature and high humidity environment, allowing moisture to penetrate into the display area.

Implementations of the present disclosure can provide a display device that may prevent moisture penetration.

The problems to be solved in the present specification are not limited to the problems mentioned above, and other problems not mentioned will be clearly understood by those skilled in the art to which the technical ideas of the present specification belong from the following description.

The advantages and features of the present specification, and methods of achieving them will be apparent from the implementations described in detail below in conjunction with the accompanying drawings. However, the present specification is not limited to the following implementations disclosed herein, but may be implemented in various different forms; rather, the present implementations are provided to make the disclosure of the present specification complete and to enable those skilled in the art to fully comprehend the scope of the present specification.

The shapes, sizes, proportions, angles, numbers, and the like of elements shown in the drawings to illustrate implementations of the present specification are merely illustrative and are not intended to be limiting. Identical reference numerals may designate identical components throughout the description. Further, in describing the present specification, detailed descriptions of related known technologies may be omitted so as not to obscure the essence of the present specification. Terms such as “comprising,” “including,” “having,” or “consisting of” as used herein are generally intended to allow for the addition of other components, unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” or “next to” describes the positional relationship of two parts, one or more other parts may be located between the two parts, unless “immediately” or “directly” is used.

When describing a temporal relationship, “after,” “following,” “next to,” or “before” describes a temporal antecedent or consequent relationship, which may not be continuous unless “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), or (b) may be used to describe elements of the implementations of the present specification. Such terms are intended only to distinguish one component from another and are not intended to define the nature, sequence, order, or number of such components. When a component is described as “connected,” “coupled,” or “attached” to another component, it is to be understood that the component may be directly connected or attached to the other component, but that there may also be other components “interposed” between the respective components which may be indirectly connected or attached where not specifically stated.

It should be understood that the term “at least one” includes all possible combinations of one or more related components. For example, the meaning of “at least one of the first, second, and third components” can be understood to include not only the first, second, or third component, but also any combination of two or more of the first, second, and third components.

Each of the features of various implementations described herein may be coupled or combined with one another in whole or in part, and may be technologically interlocked and operated in various ways, and each of the implementations may be carried out independently or in conjunction with one another.

Hereinafter, implementations of the present specification are illustrated by way of the accompanying drawings and examples. The dimensions of the components shown in the drawings are provided for illustrative purposes only and may not scale with the actual components, and the actual dimensions are not limited to the ones shown in the drawings.

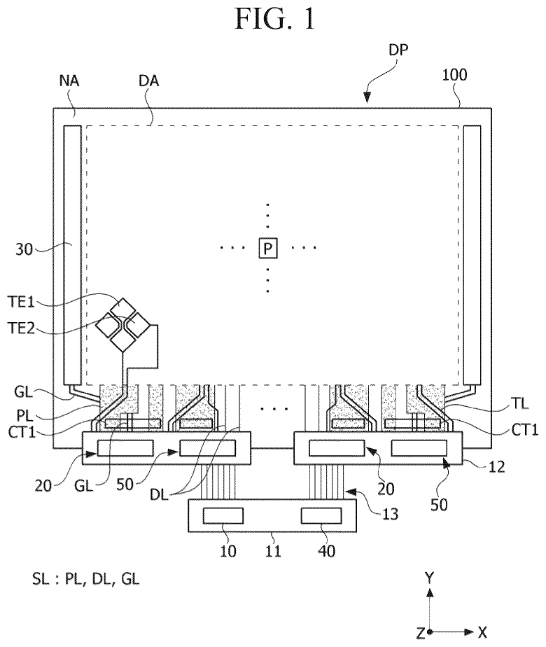

FIG. 1 illustrates an example of a display device according to an implementation. The display device includes a display panel DP substrate 100 on which a plurality of data lines and a plurality of gate lines are disposed and a plurality of pixels P are disposed, a data driver 20 connected to the display panel DP and driving the plurality of data lines, a gate driver 30 driving the plurality of gate lines, and a timing controller 10.

The display panel DP may be a rectangular panel having a length in an X-axis direction (or a first direction), a width in a Y-axis direction (or a second direction), and a thickness in a Z-axis direction (or a third direction), but is not limited thereto. For example, the display panel DP may be a deformed panel having at least a portion that is curved or elliptical. Also, the display panel DP may be composed of a plurality of physically separated sub-panels.

A display area DA of the display panel DP includes a pixel array that displays an input image. The pixel array includes a plurality of data lines, a plurality of gate lines crossing the data lines, and a plurality of pixels P arranged in a matrix form. The display panel DP may further include power wire commonly connected to the plurality of pixels P. The power wire may be commonly connected to pixel circuits to supply voltages necessary for driving the pixels to the pixels.

Each of the plurality of pixels P may be divided into red, green, and blue sub-pixels for color implementation. Each of the plurality of pixels may further include a white sub-pixel. Each sub-pixel includes a pixel circuit for driving a light-emitting element. The light-emitting element may be implemented as an organic light-emitting element such as an OLED or an inorganic light-emitting element such as a micro LED (Light Emitting Diode), but is not limited thereto. Each pixel circuit may be connected to a data line, a gate line, and power wire. Hereinafter, a pixel may be interpreted as a sub-pixel.

The data driver 20 receives pixel data of an input image received as a digital signal from the timing controller 10 and outputs a data voltage. The data driver 20 may receive gamma reference voltages and generate gamma compensation voltages for respective gray levels through a voltage divider circuit. The gamma compensation voltage for each gray level may be supplied to digital-to-analog converters (hereinafter referred to as “DAC”) disposed in each channel of the data driver 20.

The data driver 20 samples and latches digital data received from the timing controller 10, and then inputs the digital data to the DAC. Here, the digital data includes pixel data of an input image. The DAC converts the pixel data to the gamma compensation voltages and outputs data voltages of the pixel data.

The gate driver 30 may be formed on the display panel DP together with circuit elements and wires of the display area DA. The gate driver 30 may be disposed in at least one non-display area NA among left and right sides outside the display area DA in the display panel DP, or at least a portion thereof may be disposed within the display area DA.

The gate driver 30 may be disposed in non-display areas NA on both sides of the display panel DP with the display area DA of the display panel DP therebetween to supply gate pulses in a double feeding manner from both sides to the gate lines. In another implementation, the gate driver 30 may be disposed on at least one side among the left and right non-display areas NA of the display panel DP to supply gate signals to the gate lines in a single feeding manner. The gate driver 30 sequentially outputs pulses of gate signals to the gate lines under control of the timing controller 10. The gate driver 30 may sequentially supply the signals to the gate lines by shifting pulses of gate signals using a shift register or an edge trigger.

A touch sensing part 50 supplies a driving signal to a first touch electrode TE1 and detects a sensing signal from a second touch electrode TE2, and based on this, may sense presence/absence of touch and/or touch position (touch coordinates). The touch sensing part 50 may be implemented as one or two or more components (e.g., integrated circuits) and may be implemented separately from the data driver 20. However, implementations of the present specification are not limited thereto. The data driver 20 and the touch sensing part 50 may be implemented as one integrated circuit.

The timing controller 10 receives digital video data of an input image and timing signals synchronized with the data from a host system. The timing signals may include a vertical synchronization signal, a horizontal synchronization signal, a data enable signal, and the like. Since vertical periods and horizontal periods may be known by counting the data enable signal, the vertical synchronization signal and the horizontal synchronization signal may be omitted. The horizontal synchronization signal and the data enable signal have a period of one horizontal period (1H).

The timing controller 10 may generate a data timing control signal for controlling operation timing of the data driver 20, a gate timing control signal for controlling operation timing of the gate driver 30, and the like based on the timing signals received from the host system.

The data driver 20 and the touch sensing part 50 may be connected to bonding pads of the display panel DP by a Tape Automated Bonding (TAB) method or a Chip On Glass (COG) method. Alternatively, the data driver 20 and the touch sensing part 50 may be directly disposed on the display panel DP. Alternatively, the data driver 20 and the touch sensing part 50 may be integrated and disposed on the display panel DP. Also, each integrated circuit may be implemented by a Chip On Film (COF) method. In this case, integrated circuits functioning as the data driver 20 and the touch sensing part 50 are mounted on a flexible film, wherein one end of the flexible film may be bonded to a source printed circuit board 12, and the other end may be bonded to the display panel DP.

The source printed circuit board 12 may be located around the display panel DP and may be connected to a control printed circuit board 11 through a flexible flat cable (FFC) 13. The source printed circuit board 12 may receive voltages and signals for driving the display panel DP from the control printed circuit board 11 and process them.

The timing controller 10 is disposed on the control printed circuit board 11. On the control printed circuit board 11, a power supply 40 that supplies various voltages or currents to the display panel DP, the data driver 20, the gate driver 30, and the like, or controls various voltages or currents to be supplied may be further disposed.

The driving wire SL may have a power wire PL such as a low-potential voltage wire and a high-potential voltage wire disposed at the edges of the non-display area NA, and a data wire DL disposed in the central portion. The power wire PL and the data wire DL may not overlap and may be spaced apart from each other.

A touch wire TL may be connected to touch electrodes TE1 and TE2 of the display area DA and may extend to the non-display area NA. In the non-display area NA, the touch wire TL may be disposed on the power wire PL. Therefore, a portion of the touch wire TL may overlap with the power wire PL. Herein, overlapping may mean being disposed to overlap in a thickness direction (or Z-axis direction) of the panel. The touch wire TL may be disposed so as not to overlap with the data wire DL.

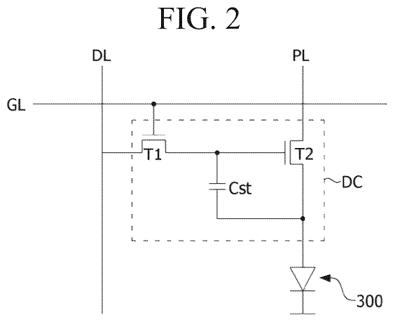

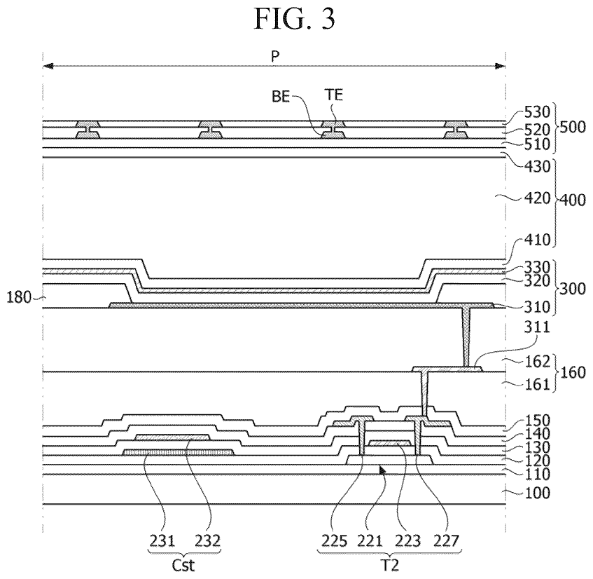

FIGS. 2 and 3 illustrate further details of the display device, in which a pixel driving circuit DC of each pixel P may supply a driving current corresponding to a data signal according to a gate signal to a light-emitting element 300 of each pixel P during one frame. For example, the pixel driving circuit DC of each pixel P may include a first thin film transistor T1, a second thin film transistor T2, and a storage capacitor Cst. However, implementations of the present specification are not limited thereto. For example, the pixel driving circuit may include three or more thin film transistors.

Referring to FIGS. 2 and 3, a substrate 100 may include an insulating material. For example, the substrate 100 may include glass or plastic.

The light-emitting element 300 of each pixel P may emit light representing a specific color. For example, the light-emitting element 300 of each pixel P may include a first electrode 310, an emission layer 320, and a second electrode 330 sequentially stacked over the substrate 100.

The first electrode 310 may include a conductive material. The first electrode 310 may include a material having high reflectivity. For example, the first electrode 310 may include a metal such as aluminum (Al) and silver (Ag). The first electrode 310 may have a multilayer structure. For example, the first electrode 310 may have a structure in which a reflective electrode made of a metal is positioned between transparent electrodes made of a transparent conductive material such as ITO and IZO.

The emission layer 320 may generate light having a luminance corresponding to a voltage difference between the first electrode 310 and the second electrode 330. For example, the emission layer 320 may include an emission material layer (EML) including an emission material. The emission material may include an organic material, an inorganic material, or a hybrid material. For example, the display device according to the implementation of the present specification may be an organic light-emitting display device including an organic emission material.

The emission layer 320 may have a multilayer structure. For example, the emission layer 320 may include a hole injection layer (HIL), a hole transport layer (HTL), an electron transport layer (ETL), and an electron injection layer (EIL).

The second electrode 330 may include a conductive material. The second electrode 330 may include a different material from the first electrode 310. The transmittance of the second electrode 330 may be greater than the transmittance of the first electrode 310. For example, the second electrode 330 may be a transparent electrode made of a transparent conductive material such as ITO and IZO. Accordingly, in the display device according to the implementation of the present specification, light generated by the emission layer 320 may be emitted to the outside through the second electrode 330.

The second thin film transistor T2 may include a second semiconductor pattern 221, a second gate electrode 223, a second drain electrode 225, and a second source electrode 227. The second thin film transistor T2 may generate a driving current corresponding to a data signal. For example, the second thin film transistor T2 may be a driving thin film transistor.

The second semiconductor pattern 221 may include a semiconductor material. For example, the second semiconductor pattern 221 may include an oxide semiconductor such as amorphous silicon (a-Si), polycrystalline silicon (Poly-Si), or IGZO.

The second gate electrode 223 may include a conductive material. For example, the second gate electrode 223 may include a metal such as aluminum (Al), chromium (Cr), copper (Cu), molybdenum (Mo), titanium (Ti), and tungsten (W).

The second gate electrode 223 may be located over the second semiconductor pattern 221. The second gate electrode 223 may be insulated from the second semiconductor pattern 221.

The storage capacitor Cst may maintain a signal applied to the second gate electrode 223 of the second thin film transistor T2 during one frame. For example, the storage capacitor Cst may be electrically connected to the second thin film transistor T2. In some implementations, the storage capacitor Cst may have a stacked structure of capacitor electrodes 231 and 232. For example, the storage capacitor Cst may include the first capacitor electrode 231 and the second capacitor electrode 232. At least one of the capacitor electrodes 231 and 232 may be formed using a formation process of the first thin film transistor T1 and the second thin film transistor T2. For example, the first capacitor electrode 231 may include the same material as the second gate electrode 223. The second capacitor electrode 232 may include the same material as the second drain electrode 225 and the second source electrode 227. The second capacitor electrode 232 may be located on the same layer as the second drain electrode 225 and the second source electrode 227. The second capacitor electrode 232 may be located on a different layer from the second drain electrode 225 and the second source electrode 227.

A plurality of insulating layers may be disposed over the substrate 100 to prevent unnecessary electrical connections within each pixel P. For example, the plurality of insulating layers can include a buffer layer 110, a gate insulating layer 120, a first insulating layer (which can include a lower interlayer insulating layer 130 and/or an upper interlayer insulating layer 140), a device protective layer 150, a planarization layer 160, and a bank layer 180, which are disposed over the substrate 100. The planarization layer 160 may be formed of a lower planarization layer 161 and an upper planarization layer 162, but the implementations of the present specification are not limited thereto. For example, the planarization layer 160 may be formed of a single layer.

The buffer layer 110 may be located close to, e.g., directly on, the substrate 100. The buffer layer 110 may prevent contamination due to the substrate 100 during the formation process of the pixel driving circuit located in each pixel P. For example, the upper surface of the substrate 100 facing the pixel driving circuit of each pixel P may be completely covered by the buffer layer 110.

The buffer layer 110 may include an insulating material. For example, the buffer layer 110 may include an inorganic insulating material such as silicon oxide (SiOx) and silicon nitride (SiNx). In some implementations, the buffer layer 110 may have a multilayer structure. For example, the buffer layer 110 may have a stacked structure of an inorganic insulating layer made of silicon oxide (SiOx) and an inorganic insulating layer made of silicon nitride (SiNx).

The gate insulating layer 120 may be located on the buffer layer 110. The gate insulating layer 120 may insulate between the semiconductor pattern and the gate electrode of each thin film transistor T1 and T2. The second gate electrode 223 of each pixel P may be located on the gate insulating layer 120. The first capacitor electrode 231 of each pixel P may be located on the gate insulating layer 120. The gate insulating layer 120 may include an insulating material. For example, the gate insulating layer 120 may include an inorganic insulating material such as silicon oxide (SiOx) and silicon nitride (SiNx).

The lower interlayer insulating layer 130 and the upper interlayer insulating layer 140 may insulate the drain electrode and the source electrode of each thin film transistor T1 and T2 from the gate electrode of the thin film transistor T1 and T2.

The upper interlayer insulating layer 140 may be located on the lower interlayer insulating layer 130. For example, the lower interlayer insulating layer 130 may cover the second gate electrode 223 of each pixel P.

The lower interlayer insulating layer 130 and the upper interlayer insulating layer 140 may include an insulating material. For example, the lower interlayer insulating layer 130 and the upper interlayer insulating layer 140 may include an inorganic insulating material such as silicon oxide (SiOx) and silicon nitride (SiNx). The second capacitor electrode 232 of the pixel P may be located between the lower interlayer insulating layer 130 and the upper interlayer insulating layer 140.

The lower interlayer insulating layer 130 and/or the upper interlayer insulating layer 140 may be defined as a first insulating layer. The lower interlayer insulating layer 130 and/or the upper interlayer insulating layer 140 may be formed as a single interlayer insulating layer.

The lower planarization layer 161 and the upper planarization layer 162 may be sequentially stacked over the upper interlayer insulating layer 140. For example, the lower planarization layer 161 may be located between the device protective layer 150 and the upper planarization layer 162. The lower planarization layer 161 and the upper planarization layer 162 may remove a step caused by the pixel driving circuit DC of each pixel P. For example, the upper surface of the upper planarization layer 162 facing away from the substrate 100 may be a flat plane.

The lower planarization layer 161 and the upper planarization layer 162 may include an insulating material. For example, the lower planarization layer 161 and the upper planarization layer 162 may include an organic insulating material. The upper planarization layer 162 may include a different material from the lower planarization layer 161. In the present specification, the planarization layer is described as being divided into the lower planarization layer 161 and the upper planarization layer 162, but is not limited thereto. For example, the planarization layer 160 may be formed of a single layer.

The light-emitting element 300 of each pixel P may be located on the upper planarization layer 162. For example, the first electrode 310, the emission layer 320, and the second electrode 330 of each pixel P may be sequentially stacked over the upper surface of the upper planarization layer 162 located within the pixel P. The first electrode 310 of each pixel P may be in direct contact with the upper surface of the upper planarization layer 162.

An intermediate electrode 311 may be located between the lower planarization layer 161 and the upper planarization layer 162. The intermediate electrode 311 may include a conductive material. For example, the intermediate electrode 311 may include a metal such as aluminum (Al), chromium (Cr), copper (Cu), molybdenum (Mo), titanium (Ti), and tungsten (W). The first electrode 310 of each pixel P may be electrically connected to the second source electrode 227 of the pixel P through one of the intermediate electrodes 311. For example, each intermediate electrode 311 may penetrate the lower planarization layer 161 of each pixel P and directly contact the second source electrode 227 of the pixel P, and the first electrode 310 of each pixel P may penetrate the upper planarization layer 162 of the pixel P and directly contact one of the intermediate electrodes 311.

The bank layer 180 may be located on the upper planarization layer 162. The bank layer 180 may define an emission area within each pixel P. For example, the bank layer 180 may cover edges of the first electrode 310 located within each pixel P. The emission layer 320 and the second electrode 330 of each pixel P may be sequentially stacked on a partial area of the first electrode 310 exposed by the bank layer 180. The bank layer 180 may include an insulating material. For example, the bank layer 180 may include an organic insulating material. The bank layer 180 may include a different material from the upper planarization layer 162.

At least a portion of the emission layer 320 of each pixel P may extend outside the pixel P. For example, at least one of the hole injection layer (HIL), the hole transport layer (HTL), the electron transport layer (ETL), and the electron injection layer (EIL) located within each pixel P may extend onto the bank layer 180. At least one of the hole injection layer (HIL), the hole transport layer (HTL), the electron transport layer (ETL), and the electron injection layer (EIL) located within each pixel P may be formed simultaneously with the corresponding layer located within the adjacent pixel P. For example, at least one of the hole injection layer (HIL), the hole transport layer (HTL), the electron transport layer (ETL), and the electron injection layer (EIL) may be formed over the entire surface of the substrate 100. Accordingly, the process efficiency may be improved in the display device according to the implementation of the present specification.

An encapsulation part 400 may be located on the light-emitting element 300 of each pixel P. The encapsulation part 400 may prevent damage to the light-emitting elements 300 due to external moisture and impact. For example, the light-emitting elements 300 of each pixel P may be completely covered by the encapsulation part 400.

The encapsulation part 400 may have a multilayer structure. For example, the encapsulation part 400 may include a first encapsulation layer 410, a second encapsulation layer 420, and a third encapsulation layer 430. The first encapsulation layer 410, the second encapsulation layer 420, and the third encapsulation layer 430 may include an insulating material.

The second encapsulation layer 420 may include a different material from the first encapsulation layer 410 and the third encapsulation layer 430. For example, the first encapsulation layer 410 and the third encapsulation layer 430 may include an inorganic insulating material, and the second encapsulation layer 420 may include an organic insulating material. Accordingly, in the display device according to the implementation of the present specification, damage to the light-emitting elements 300 due to external moisture and impact may be effectively prevented. In some implementations, the step formed by the light-emitting elements 300 may be planarized by the second encapsulation layer 420. For example, the upper surface of the encapsulation part 400 facing away from the substrate 100 on the pixel areas may be a flat plane.

A touch sensing layer 500 including a plurality of touch electrodes TE may be arranged on the encapsulation part 400. The plurality of touch electrodes TE may be electrically connected to a bridge electrode BE. In some implementations, the touch sensing layer 500 may include a second insulating layer such as a touch buffer layer 510 arranged on the encapsulation part 400, a bridge electrode BE arranged on the touch buffer layer 510, a touch interlayer insulating layer 520 arranged over the touch buffer layer 510 and the bridge electrode BE, and a touch electrode TE arranged on the touch interlayer insulating layer 520. In this case, the bridge electrode BE and the touch electrode TE may include the same material.

The second insulating layer, e.g., touch buffer layer 510, may block a chemical solution such as a developer or an etchant used in the manufacturing process of the touch electrodes, or external moisture or foreign substances from penetrating into the light-emitting element. Hereinafter, the touch buffer layer 510 is described as an implementation of the second insulating layer.

The bridge electrode BE is arranged in the display area DA and electrically connects the touch electrodes TE on the touch interlayer insulating layer 520.

The touch interlayer insulating layer 520 may be arranged on the touch buffer layer 510 to cover the bridge electrode BE to insulate the bridge electrode BE and the touch electrode TE. A portion of the touch electrode TE may be connected to the bridge electrode BE by a through hole. In addition, the touch interlayer insulating layer 520 may be arranged between the bridge electrodes BE to insulate the bridge electrodes BE from each other.

The touch buffer layer 510 and/or the touch interlayer insulating layer 520 may be made of an inorganic insulating material such as silicon nitride (SiNx) or silicon oxide (SiOx).

A touch protective layer 530 may be arranged over the touch electrode. The touch protective layer 530 may serve to prevent oxidation, corrosion, or damage of the touch electrode and the touch wire. The touch protective layer 530 may be made of at least one or more of an inorganic insulating material such as silicon nitride (SiNx) or silicon oxide (SiOx), or an organic insulating material such as benzocyclobutene (BCB), acrylic resin, epoxy resin, phenolic resin, polyamide resin, or polyimide resin, but is not limited thereto.

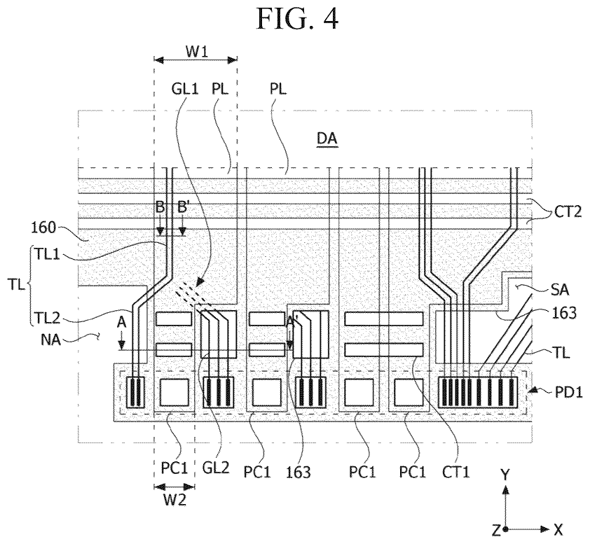

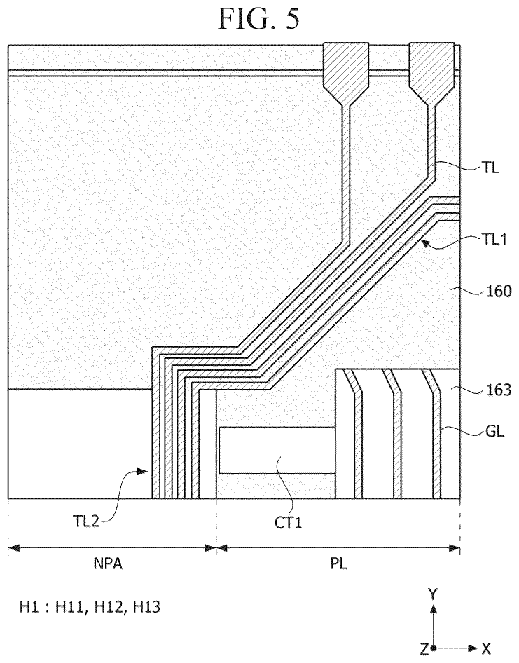

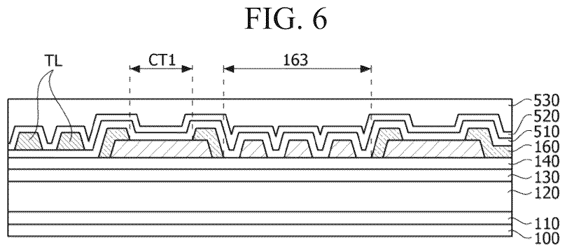

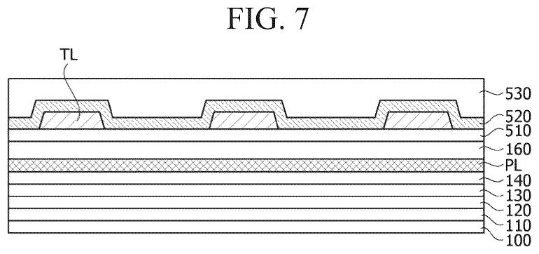

FIG. 4 is a partially enlarged view of an example of a display device according to an implementation of the present specification. FIG. 5 is a diagram showing an example of an open area of a planarization layer according to an implementation of the present specification. FIG. 6 is a cross-sectional view taken along the line A-A′ of FIG. 4. FIG. 7 is a cross-sectional view taken along the line B-B′ of FIG. 4.

Referring to FIGS. 4 to 6, a power wire PL may extend from the display area DA to a pad part PD1. A line width W1 of the power wire PL may be relatively wider than the line widths of the data wire DL, the gate wire GL, and the touch wire TL. Therefore, when the power wire PL having a wide line width may occupy a large area of the pad part PD1, areas of the data wire DL, the gate wire GL, and the touch wire TL connected to the pad part PD1 may be reduced. Taking this into account, the power wire PL may include a pad connection portion PC1 having a relatively narrow line width W2. Since the pad connection portion PC1 of the power wire PL has a relatively narrow line width W2, a separation area SA may be generated between a plurality of pad connection portions PC1. The gate wire GL and the touch wire TL may extend to the separation area SA to be connected to the pad part PD1.

The planarization layer 160 may be disposed on the power wire PL and the data wire DL. The planarization layer 160 may help prevent damage to the mask for forming the touch sensing layer on the upper portion of the display panel, e.g., help prevent damage to the mask caused by contact with the power wire PL or the like.

The planarization layer 160, when formed in the display area DA, may also be formed in a portion of the non-display area NA. For example, the planarization layer 160 may be formed in the area where the power wire PL and the data wire DL are arranged in the non-display area NA, and may not be formed in the remaining non-display area NA. The planarization layer 160 may not be arranged in the separation area SA between the pad connection portions PC1 of the power wire PL.

The planarization layer 160 may include an open area 163 corresponding to the separation area SA between the pad connection portions PC1 of the power wire PL. The reason for this is that if the planarization layer 160 is also arranged in the separation area SA between the pad connection portions PC1 of the power wire PL, there is no space for the gate wire GL extending under the power wire PL to be connected to the pad part PD1. The gate wire GL is exposed by the separation area SA and can be connected to the pad part PD1. The open area 163 may be defined as an opening hole, an opening area, or a fourth opening hole.

The touch wire TL may extend from the display area DA over the power wire PL and the planarization layer 160. The touch wire TL and the power wire PL may be electrically insulated by the planarization layer 160. The end of the touch wire TL may be further extended to a position that does not overlap the power wire PL for connection to the pad part PD1 and may be connected to the pad part PD1. For example, the touch wire TL may include a first touch wire TL1 that extends from the display area DA over the power wire PL and a second touch wire TL2 that extends to a position that does not overlap the power wire PL and is connected to the pad part PD1.

The gate wire GL may be extended from the gate driver and may be extended under the power wire PL. The end of the gate wire GL may be further extended to a position that does not overlap the power wire PL for connection to the pad part PD1 and may be connected to the pad part PD1. For example, the gate wire GL may include a first gate wire GL1 that extends from the display area under the power wire PL and a second gate wire GL2 that extends to an open area 163 that does not overlap the power wire PL and is connected to the pad part PD1. The first gate wire GL1 that extends under the power wire PL is indicated by a dotted line. The first gate wire GL1 that extends under the power wire PL may be a link wire arranged in a different layer.

According to an implementation, since the touch wire TL extends over the power wire PL and the gate wire GL extends under the power wire PL, a large number of wires may be connected to the pad part PD1. However, implementations of the present specification are not limited thereto. For example, the touch wire TL may extend under the power wire PL, and the gate wire GL may extend over the power wire PL. For example, a portion of the gate wire GL may extend over the power wire PL, and a portion of the gate wire GL may extend under the power wire PL. In addition to the gate wire GL, various wires may extend under or over the power wire PL and be connected to the pad part PD1.

The planarization layer 160 may include a trench CT1 that prevents moisture penetration. The trench CT1 may be formed to extend in the first direction (X-axis direction) in the non-display area NA between the display area DA and the pad part PD1. The trench CT1 may be arranged between a plurality of power wires PL or touch wires TL. The trench CT1 may be defined as an opening, an opening hole, or an opening area.

The trench CT1 may be arranged in an area between a plurality of open areas 163 formed in the planarization layer 160. Since the planarization layer 160 is an organic film, it may be relatively vulnerable to moisture. According to the implementation, since the planarization layer 160 is removed from the trench CT1 and the open area 163, moisture may be prevented from penetrating into the display area DA even when the pad part PD1 is lifted.

According to the implementation, a plurality of trenches CT1 and open areas 163 may be arranged to be spaced apart from each other in the first direction (X-axis direction). The widths of the plurality of trenches CT1 and the open areas 163 may be different from each other. The width of the open area 163 may be determined by the line width W1 and W2 of the power wire PL, and the width of the trench CT1 may be determined by the distance between the open areas 163. The width may be a length extended in the first direction (X-axis direction).

The plurality of trenches CT1 and the open areas 163 may be arranged only in the edge area where the power wire PL is arranged. The trenches CT1 and the open areas 163 may not be formed in the central portion where the data wire DL is located. However, implementations of the present disclosure are not limited thereto. For example, the trench CT1 and/or the open area 163 may be formed in a portion where a planarization layer 160 is formed, even in the area where the data wire DL is located. In addition, a second trench CT2 may be additionally formed between the open area 163 and the display area DA to further prevent moisture penetration.

Referring to FIG. 7, the touch line TL may be disposed over the power wire PL. The trench CT1 may not be formed in the area where the touch line TL is disposed. If the trench CT1 is formed in an area where the touch line TL is disposed, then this may disrupt the flatness of the touch line TL, resulting in disconnection.

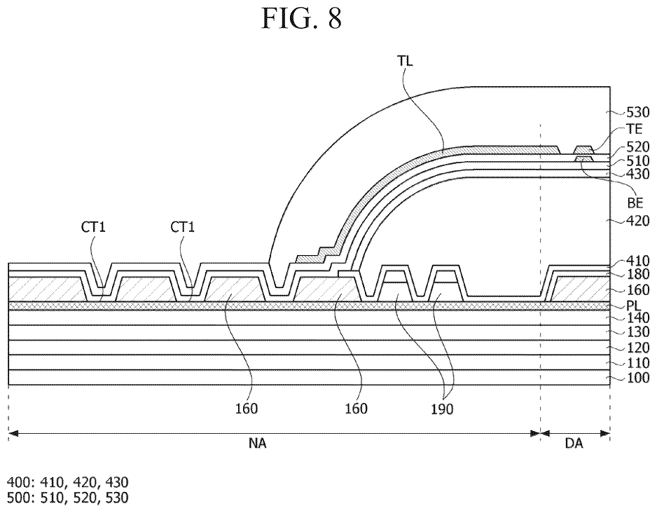

FIG. 8 is a cross-sectional view of an example of the display device according to an implementation of the present specification.

Referring to FIG. 8, a plurality of insulating layers may be located over the substrate. For example, the plurality of insulating layers can include the buffer layer 110, the gate insulating layer 120, the lower interlayer insulating layer 130, the upper interlayer insulating layer 140, the planarization layer 160, and the bank layer 180 that are sequentially located over the substrate 100.

The encapsulation part 400 may be located in the display area. The encapsulation part 400 may prevent damage to the light-emitting elements 300 due to external moisture and impact. The encapsulation part 400 may have a multilayer structure. For example, the encapsulation part 400 may include the first encapsulation layer 410, the second encapsulation layer 420, and the third encapsulation layer 430 that are sequentially stacked. The first encapsulation layer 410, the second encapsulation layer 420, and the third encapsulation layer 430 may include an insulating material.

The touch sensing layer 500 including the plurality of touch electrodes TE may be arranged on the encapsulation part 400. The plurality of touch electrodes may be connected to bridge electrodes BE arranged on different layers. Specifically, the touch sensing layer 500 may include the touch buffer layer 510 arranged on the encapsulation part 400, the bridge electrode BE arranged on the touch buffer layer 510, the touch interlayer insulating layer 520 arranged over the touch buffer layer 510 and the bridge electrode BE, and the touch electrode TE arranged on the touch interlayer insulating layer 520. The bridge electrode BE and the touch electrode TE may include the same material.

A dam 190 that blocks the flow of the second encapsulation layer 420 forming the encapsulation part 400 may be arranged on the non-display area NA. Specifically, the dam 190 is arranged in a closed curve shape surrounding the display area DA in the non-display area NA, the first encapsulation layer 410 and the third encapsulation layer 430 are arranged over the dam 190, and the second encapsulation layer 420 may have its flow blocked by the dam 190.

The dam 190 may be configured to have a height greater than a certain height to block the flow of the second encapsulation layer 420. To this end, the dam 190 may be formed of at least one layer made of an organic material. For example, the dam 190 may include a lower layer made of the same material as the planarization layer 160 and an upper layer made of the same material as the bank layer 180, but is not limited thereto. Although the drawing shows a configuration with two dams 190, the dam 190 may be provided with one or three or more.

The touch buffer layer 510 and the touch interlayer insulation layer 520 may extend over the dam 190 to extend to the non-display area NA. Therefore, a chemical solution such as a developer or an etchant used in the manufacturing process of the touch electrodes which is formed over the touch buffer layer 510, or external moisture or foreign substances may be prevented from penetrating into the light-emitting element.

A touch electrode TE and a touch wire TL are arranged on the touch interlayer insulation layer 520, and the touch wire TL may extend along the touch buffer layer 510 to the non-display area NA.

The touch protective layer 530 may be arranged over the touch wire TL. The touch protective layer 530 may serve to prevent oxidation, corrosion, or damage of the touch electrode and the touch wire.

The planarization layer 160 of the display part may extend to the non-display area NA to cover the power wire PL. The planarization layer 160 extended to the non-display area NA may include the plurality of trenches CT1. The moisture penetration path may be blocked by the plurality of trenches CT1.

The power wire PL extended to the non-display area NA may be exposed by the plurality of trenches CT1. The touch buffer layer 510 extended to the non-display area NA may contact the power wire PL to improve adhesion. As a result, the touch sensing layer may be prevented from being peeled off.

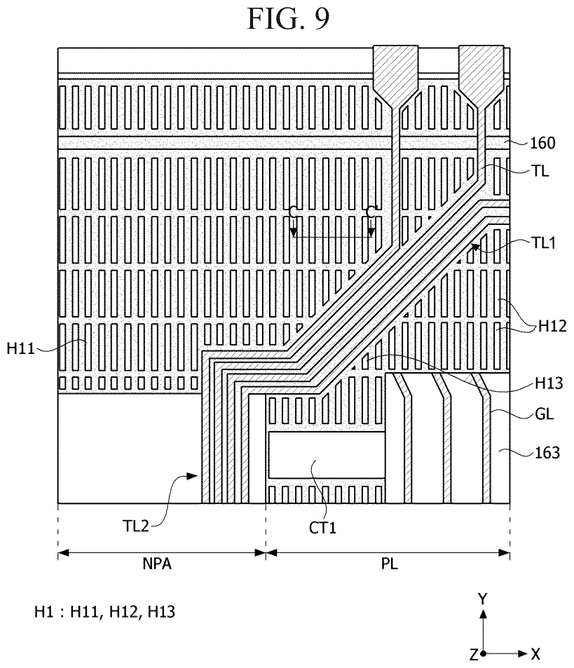

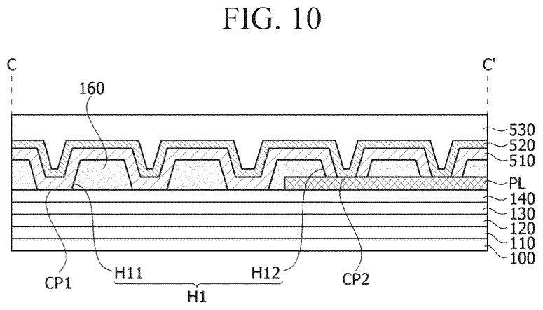

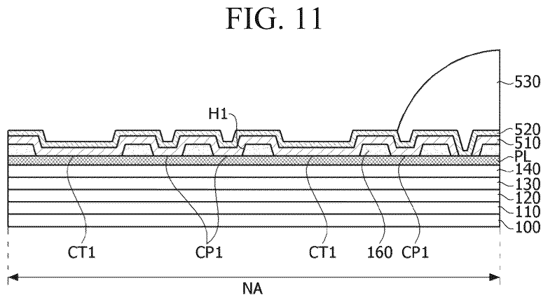

FIG. 9 is a diagram showing an example of an opening hole formed in the planarization layer according to an implementation of the present disclosure. FIG. 10 is a cross-sectional view taken along the line C-C′ of FIG. 9. FIG. 11 is a cross-sectional view of an example of a display device according to another implementation of the present disclosure.

Referring to FIG. 9, a plurality of opening holes H1 may be disposed in the planarization layer 160 in an area where the touch wire TL is not disposed in a plan view. The opening hole H1 may be a square shape in a plan view, but the implementations of the present specification are not limited thereto. For example, the opening hole H1 may have various shapes, such as a circular shape, a triangular shape, and an octagonal shape in the plan view. The opening hole H1 may not be formed in an area where the touch wire TL is disposed, so as to prevent the touch wire TL from being disconnected.

The opening hole H1 may include a first opening hole H11 disposed in an area NPA where there is no power wire PL and a second opening hole H12 disposed on the power wire PL. The sizes of the first opening hole H11 and the second opening hole H12 may be the same, but are not necessarily limited thereto. For example, a size of the first opening hole H11 may be different from a size of the second opening hole H12. For example, a shape of the first opening hole H11 may be different from a shape of the second opening hole H12.

The third opening hole H13 is arranged adjacent to the touch wire TL and may have a different size and/or shape from other opening holes. For example, the third opening hole H13 disposed closest to the touch wire TL may have a slope formed on the side facing the touch wire TL. In addition, the third opening hole H13 disposed closest to the touch wire TL may have the smallest size compared to the other opening holes. With this configuration, the maximum number of opening holes may be formed, which can have the effect of increasing the adhesion of the touch sensing layer. Moreover, by not forming opening holes near the area where the touch wire TL is disposed, this can help prevent a step from being formed in the touch wire TL.

Referring to FIG. 10, the driving wire including the power wire PL may be disposed on upper interlayer insulating layer 140. The planarization layer 160 may be disposed on the driving wire including the power wire PL. The opening hole H1 of the planarization layer 160 may expose the upper interlayer insulating layer 140. Therefore, in the process of applying the touch buffer layer 510 over the planarization layer 160, the touch buffer layer 510 and the touch interlayer insulating layer 520 may extend into the opening hole H1 and may be contacted with the upper interlayer insulating layer 140.

In scenarios where the planarization layer 160 is an organic material, its adhesion to the inorganic touch buffer layer 510 disposed thereon may be relatively weak. However, according to the implementation, since the inorganic upper interlayer insulating layer 140 and the inorganic touch buffer layer 510 come into contact through the opening hole H1, the adhesion to the inorganic touch buffer layer 510 may be relatively strong. Therefore, the adhesion between the display panel and the touch sensing layer may be improved when subjected to external force or bending. Therefore, this can provide a technical effect of mitigating a risk that the touch wire TL disposed on the touch buffer layer 510 is lifted or peeled off.

In this example, the opening hole H1 may include a first opening hole H11 exposing the upper interlayer insulating layer 140 of the display panel and a second opening hole H12 exposing the power wire PL.

Each opening hole can create a respective contact point between the touch buffer layer 510 and the upper interlayer insulating layer 140. For example, the touch buffer layer 510 may include a first contact part CP1 that is bonded to the upper interlayer insulating layer 140 in an area where the first opening hole H11 is disposed, and a second contact part CP2 that is bonded to the power wire PL in the area where the second opening hole H12 is disposed. Therefore, since the touch buffer layer 510 is bonded to the upper interlayer insulating layer 140 and also to the power wire PL, the overall adhesion of the touch buffer layer 510 may be improved.

The first opening hole H11 and the second opening hole H12 may have the same shape and/or size, but the implementations of the present specification are not limited thereto. For example, the first opening hole H11 may be larger than the second opening hole H12. For example, the first opening hole H11 may be smaller than the second opening hole H12.

Referring to FIG. 11, the planarization layer 160 extended to the non-display area NA may include a plurality of opening holes H1 and trenches CT1. The moisture penetration path may be blocked by the plurality of trenches CT1.

The power wire PL extended to the non-display area NA may be exposed by the plurality of opening holes H1 and trenches CT1. The touch buffer layer 510 extended to the non-display area NA may contact the power wire PL to improve adhesion. As a result, this can have the effect of reducing the risk that the touch sensing layer is peeled off.

The display device according to various implementations of the present specification may be described as follows.

The display device according to one or more implementations of the present specification may include: a substrate including a display area and a non-display area; a driving wire extending from the display area to the non-display area; a planarization layer arranged on the driving wire; and a touch wire arranged over the planarization layer, wherein the planarization layer may include a trench arranged on the driving wire, and the trench may not overlap the touch wire in a plan view.

The display device according to one or more implementations of the present specification may further include a pad part connected to the driving wire and the touch wire, wherein the trench may be arranged in a non-display area between the display area and the pad part in the plan view.

According to one or more implementations of the present specification, the driving wire may include a plurality of power wires and a plurality of data wires, and the trench may be arranged on at least one of the plurality of power wires.

According to one or more implementations of the present specification, each of the power wires may include a pad connection portion connected to the pad part arranged in the non-display area, and the trench may be arranged on the pad connection portion of at least one of the power wires.

The display device according to one or more implementations of the present specification may further include a plurality of separation areas arranged between the pad connection portions of the power wires, and the planarization layer may include a plurality of open areas arranged in the separation areas.

According to one or more implementations of the present specification, the trench may be arranged between the plurality of open areas.

According to one or more implementations of the present specification, the plurality of trenches are arranged between the plurality of open areas and have different lengths.

According to one or more implementations of the present specification, the touch wire may include (i) a first touch wire that extends from the display area and is arranged over at least one of the power wires and (ii) a second touch wire that is connected from the first touch wire to the pad part arranged in the non-display area, and the second touch wire may not overlap any of the power wires.

According to one or more implementations of the present specification, the driving wire may further include gate wire, the gate wire may include (i) a first gate wire that extends from the display area and is arranged under the power wires and (ii) a second gate wire that is connected from the first gate wire to the pad part arranged in the non-display area, and the second gate wire may not overlap any of the power wires.

According to one or more implementations of the present specification, the second gate wire may be connected to the pad part through the open area.

According to one or more implementations of the present specification, the planarization layer may include a plurality of opening holes arranged between the trench and the display area, and the plurality of opening holes may be arranged offset from the touch wire in the plan view.

The display device according to one or more implementations of the present specification may further include a first insulating layer arranged between the substrate and the driving wire; and a second insulating layer arranged between the planarization layer and the touch wire, wherein the second insulating layer may contact the first insulating layer exposed through a first opening hole among the plurality of opening holes.

According to one or more implementations of the present specification, the plurality of opening holes may include (i) a first opening hole that does not overlap any of the power wires and (ii) a second opening hole that is arranged on the power wires.

According to one or more implementations of the present specification, the first opening hole and the second opening hole may have different sizes.

According to one or more implementations of the present specification, an opening hole arranged closest to the touch wire among the plurality of opening holes may have the smallest area, in the plan view, among the plurality of opening holes.

According to one or more implementations of the present specification, the first insulating layer and the second insulating layer may include an inorganic material, and the planarization layer may include an organic material.

The display device according to one or more implementations of the present specification may further include a dam arranged in the non-displayed area, wherein the opening hole may be arranged between the dam and the trench.

The display device according to one or more implementations of the present specification may further include: a data driver circuit configured to apply a data signal to a pixel of the display area; a gate driver circuit configured to apply a gate signal to the pixel of the display area; and a touch sensing circuit connected to the touch wire and configured to receive a touch signal.

The display device according to one or more implementations of the present specification may further include a timing controller circuit configured to control the data driver circuit, the gate driver circuit, and the touch sensing circuit.

The display device according to one or more implementations of the present specification may further include a first substrate on which the timing controller circuit is arranged; a second substrate on which the data driver circuit and the touch sensing circuit are arranged; and a flexible cable connecting the first substrate and the second substrate.

What is claimed is:

1. A display device comprising:
a substrate including a display area and a non-display area;
a driving wire extending from the display area to the non-display area;
a planarization layer arranged on the driving wire; and
a touch wire arranged over the planarization layer,
wherein the planarization layer includes a trench arranged on the driving wire, and
wherein the trench does not overlap the touch wire in a plan view.

2. The display device according to claim 1, further comprising:
a pad part connected to the driving wire and the touch wire,
wherein the trench is arranged in a non-display area between the display area and the pad part in the plan view.

3. The display device according to claim 2, wherein:
the driving wire includes a plurality of power wires and a plurality of data wires, and
the trench is arranged on at least one of the plurality of power wires.

4. The display device according to claim 3, wherein:
each of the plurality of power wires includes a pad connection portion connected to the pad part arranged in the non-display area, and
the trench is arranged on the pad connection portion of the least one of the plurality of power wires.

5. The display device according to claim 4, further comprising:
a plurality of separation areas arranged between pad connection portions of the plurality of power wires,
wherein the planarization layer includes a plurality of open areas arranged in the separation areas.

6. The display device according to claim 5, wherein the trench is arranged between the plurality of open areas.

7. The display device according to claim 6, wherein the trench comprises a plurality of trenches, and the plurality of trenches are arranged between the plurality of open areas and have different lengths.

8. The display device according to claim 5, wherein:
the touch wire includes (i) a first touch wire extending in the display area and arranged over at least one of the plurality of power wires and (ii) a second touch wire connected from the first touch wire to the pad part disposed in the non-display area, and
the second touch wire does not overlap any of the plurality of power wires.

9. The display device according to claim 5, wherein the driving wire further includes a gate wire,
the gate wire includes (i) a first gate wire extending from the display area and arranged under the plurality of power wires and (ii) a second gate wire connected from the first gate wire to the pad part disposed in the non-display area, and
the second gate wire does not overlap any of the plurality of power wires.

10. The display device according to claim 9, wherein the second gate wire is connected to the pad part through an open area among the plurality of open areas.

11. The display device according to claim 3, wherein:
the planarization layer includes a plurality of opening holes arranged between the trench and the display area, and
the plurality of opening holes are arranged offset from the touch wire in the plan view.

12. The display device according to claim 11, further comprising:
a first insulating layer arranged between the substrate and the driving wire; and
a second insulating layer arranged between the planarization layer and the touch wire,
wherein the second insulating layer contacts the first insulating layer exposed through a first opening hole among the plurality of opening holes of the planarization layer.

13. The display device according to claim 12, wherein the plurality of opening holes include (i) the first opening hole that does not overlap the plurality of power wires and (ii) a second opening hole that is arranged on the plurality of power wires.

14. The display device according to claim 13, wherein the first opening hole and the second opening hole have different sizes.

15. The display device according to claim 13, wherein an opening hole arranged closest to the touch wire among the plurality of opening holes has a smallest area, in the plan view, among the plurality of opening holes.

16. The display device according to claim 12, wherein:
the first insulating layer and the second insulating layer include an inorganic material, and
the planarization layer includes an organic material.

17. A display device comprising:
a substrate including a display area and a non-display area;
a driving wire extending from the display area to the non-display area;
a planarization layer arranged on the driving wire; and
touch wire, the touch wire comprises a first touch wire extending in the display area and a second touch wire extending in the non-display area,
the planarization layer includes a trench or an opening, and
wherein the trench or the opening does not overlap with the first touch wire in the display area in an up and down direction.

18. The display device according to claim 17, wherein,
the driving wire includes a plurality of power wires and a plurality of data wires,
the trench or the opening is arranged on the power wire,
the second touch wire connects the first touch wire to a pad part disposed in the non-display area, and
the second touch wire does not overlap the power wire.

19. A display device, comprising:
a substrate including a display area and a non-display area;
a first wire extending from the display area to the non-display area;
a planarization layer disposed on the first wire; and
a second wire disposed on the planarization layer,
wherein the planarization layer includes a trench, the trench exposing a layer contacting the planarization layer from below the planarization layer,
the second wire positioned in the display area is not located directly above the groove.

20. The display device according to claim 19, wherein,
the first wire is a driving wire, and the second wire is a touch wire, or the first wire is a touch wire, and the second wire is a driving wire,
wherein, a layer contacting the planarization layer from above the planarization layer contacts or connects via an intermediate structure to the layer contacting the planarization layer from below the planarization layer in the trench.
